(19) United States
(12) Patent Application Publication
(10) Pub. No.: US 2006/0176099 A1
(43) Pub. Date: Aug. 10, 2006

(54) Semiconductor integrated circuit and method of controlling the semiconductor integrated circuit

(75) Inventor: Kouji Tsunetou, Kasugai (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/132,190

(22) Filed: May 19, 2005

(30) Foreign Application Priority Data
Feb. 7, 2005 (JP) 2005-030925

(51) Int. Cl. H03K 3/01

(52) U.S. Cl. 327/534

(57) ABSTRACT

A semiconductor integrated circuit and a method of controlling the semiconductor integrated circuit are capable of performing low power consumption and an improvement in the operation speed. A variable higher reference voltage and a variable lower reference voltage are outputted from a voltage generator. The variable higher reference voltage is applied to a source terminal of a PMOS transistor, and the variable lower reference voltage is applied to a source terminal of an NMOS transistor. The variable higher reference voltage and the variable lower reference voltage are variably controlled in such a manner that a threshold voltage becomes large in the case where power saving is going to be conducted in an operation standby state or the like, and variably controlled in such a manner that the threshold voltage becomes small in the case where a processing speed is required during the operation or the like.

### CROSS-REFERENCE TO RELATED APPLICATIONS

This application is based upon and claims the benefit of priority from the prior Japanese Patent Application No. 2005-030925 filed on Feb. 7, 2005, the entire contents of which are incorporated herein by reference.

### BACKGROUND OF THE INVENTION

1. Field of the Invention

The present invention relates to a semiconductor integrated circuit and a method of controlling the semiconductor integrated circuit, and more particularly to power consumption and an improvement in the operating speed.

2. Description of the Related Art

Recent important issues that are common to all of LSI reside in that the power consumption is reduced, and the operating speed is increased. Then, in the realization of reducing the power consumption, a leakage current between power supplies in a standby state cannot be ignored. In particular, as the miniaturization of a semiconductor device is advanced, the leakage current between a source and a drain cannot be ignored with a reduction of the gate width.

A conventional semiconductor integrated circuit is shown in FIG. 4. A back bias value PBB of a PMOS transistor M110 is set to be higher than a supply voltage VDD, and a back bias value NBB of an NMOS transistor M111 is set to be lower than a ground voltage VSS, to thereby reduce the leakage current between the source and the drain.

Also, the semiconductor integrated circuit disclosed in Japanese Unexamined Patent Publication No. 2002-111470 is shown in FIG. 5. In the circuit of FIG. 5, the back bias values of the PMOS transistor and the NMOS transistor are fixed to the supply voltage VDD and the ground voltage VSS, respectively. With the structure of FIG. 5, operating supply voltages vdd1s and vss1s of the circuit block BLK 102 is made smaller than the operating supply voltages vdd1 and vss1 at the active time in response to an operating stop mode of the circuit block BLK 102. As a result, the threshold voltages of MOS transistors M100 to M103 that constitute an MOS static latch circuit LAT are made larger under the control.

The above related art is disclosed in Japanese Unexamined Patent Publication No. 2004-207749.

### SUMMARY OF THE INVENTION

In the conventional art shown in FIG. 4, the back bias value PBB is set to be higher than the supply voltage VDD, and the back bias value NBB is set to be lower than the ground voltage VSS. Because a voltage that is applied to the gate becomes high as compared with a case in which the back bias value is fixed to the supply voltage VDD and the ground voltage VSS, there is the possibility that the gate leakage current increases, which is a problem. Also, there arise such problems that a high voltage is applied to the gate, thereby deteriorating the transistor to shorten the lifetime of an LSI and lowering the reliability of the LSI. Also, a capacity of the back bias between the supply voltages is very large. As a result, when the back bias is controlled, the power consumption at the time of changing the back bias is large, and a period of time required to change the back bias is large, which is a problem.

In the conventional art disclosed in Japanese Unexamined Patent Publication No. 2002-111470, there is disclosed a power saving operation in an operation stop mode. However, there arises such a problem that the speed cannot be increased at the operation time. In particular, as the miniaturization of the transistor device is advanced, the drive performance is deteriorated whereby a requirement for increasing the speed becomes severe. This leads to such a problem that the requirement must be satisfied.

The present invention has been made to eliminate at least one of the problems with the above background art, and therefore an object of the present invention is to provide a semiconductor integrated circuit and a method of controlling the semiconductor integrated circuit, which are capable of reducing the power consumption by preventing an increase in the gate leakage current, shortening a period of time required for the voltage control of the operating supply voltage, and increasing the transistor operation speed.

To achieve the above object, a semiconductor integrated circuit according to a first idea of the present invention comprises a MOS transistor having a difference voltage of a back gate terminal voltage with respect to a source terminal voltage variously controlled among a negative voltage, a zero voltage and a positive voltage.

Further, a method of controlling semiconductor integrated circuit according to the first idea of the invention comprises the step of variably controlling a difference voltage of a back gate terminal voltage with respect to a source terminal voltage of a MOS transistor among a negative voltage, a zero voltage and a positive voltage.

A difference voltage between a source terminal voltage and a back gate terminal voltage is variably controlled between a negative voltage and a positive voltage with reference to the source terminal voltage. The difference voltage becomes a negative voltage in the case where the back gate voltage value becomes smaller than the source terminal voltage. Also, the difference voltage becomes a positive voltage in the case where the back gate voltage value becomes larger than the source terminal voltage. Further, the difference voltage becomes a zero voltage in the case where the back gate voltage value becomes equal to the source terminal voltage.

As a result, the difference voltage is variably controlled so that the threshold voltage becomes large due to a substrate bias effect, thereby making it possible to reduce the leakage current between the source and the drain of the MOS transistor. As a result, the power consumption of the semiconductor integrated circuit can be reduced.

Also, the difference voltage is variably controlled so that the threshold voltage becomes small due to the substrate bias effect, thereby as a first effect enhancing the current drive performance of the MOS transistor. As a result, it is possible to increase the operating speed of the MOS transistor. Then, as a second effect, it is possible to increase the operating speed of the MOS transistor with an increase in the voltage difference between the source and the drain. Then, the above two effects are synthesized, thereby making it possible to effectively increase the operating speed of the MOS transistor.

Then, in the case where power saving is going to be conducted during the operation standby state, the difference voltage is variably controlled so that the threshold voltage becomes large, and in the case where the processing speed during the operation is required, the difference voltage is variably controlled so that the threshold voltage becomes smaller. This makes it possible to perform both of the power saving due to a reduction in the leakage current between the power supplies and an increase in the operating speed of the MOS transistor during the operation.

The above and further objects and novel features of the invention will more fully appear from the following detailed description when the same is read in connection with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 shows a semiconductor integrated circuit 10 according to the present invention;

FIG. 2 shows a variable higher reference voltage VHV and a variable lower reference voltage VLV;

FIG. 3 shows a semiconductor integrated circuit 20 according to the present invention;

FIG. 4 shows a semiconductor integrated circuit 20 according to the present invention; and

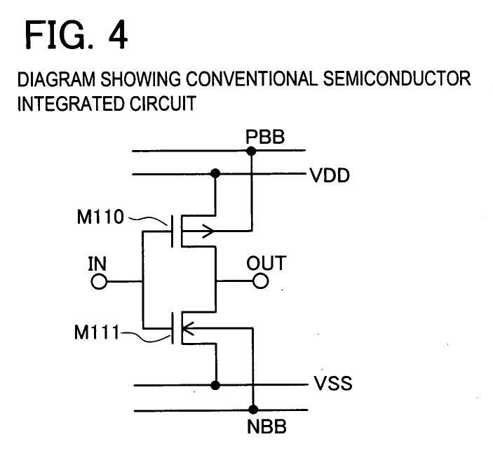

FIG. 5 shows a semiconductor integrated circuit disclosed in JP2002-11470A.

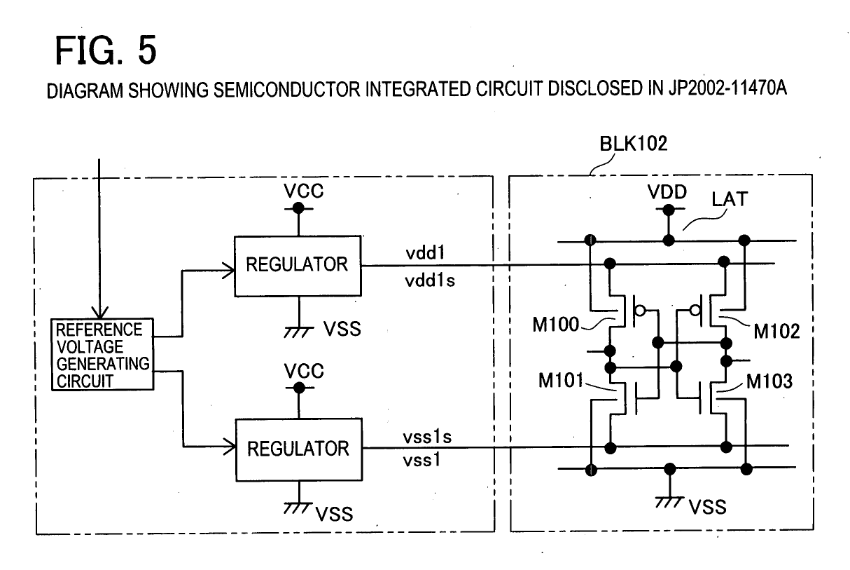

### DETAILED DESCRIPTION OF THE PREFERRED EMBODIMENTS

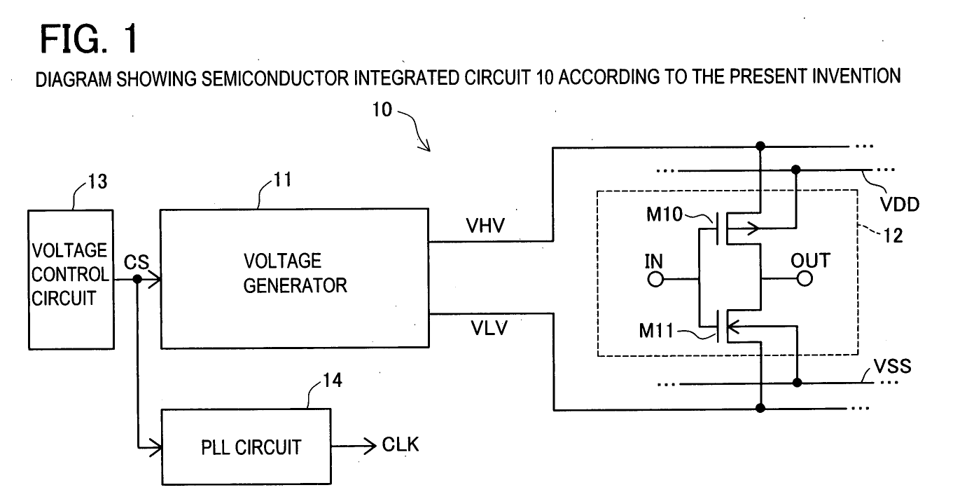

Now, a description will be given in more detail of a semiconductor integrated circuit and a method of controlling the semiconductor integrated circuit according to embodiments of the present invention with reference to FIGS. 1 to 3.

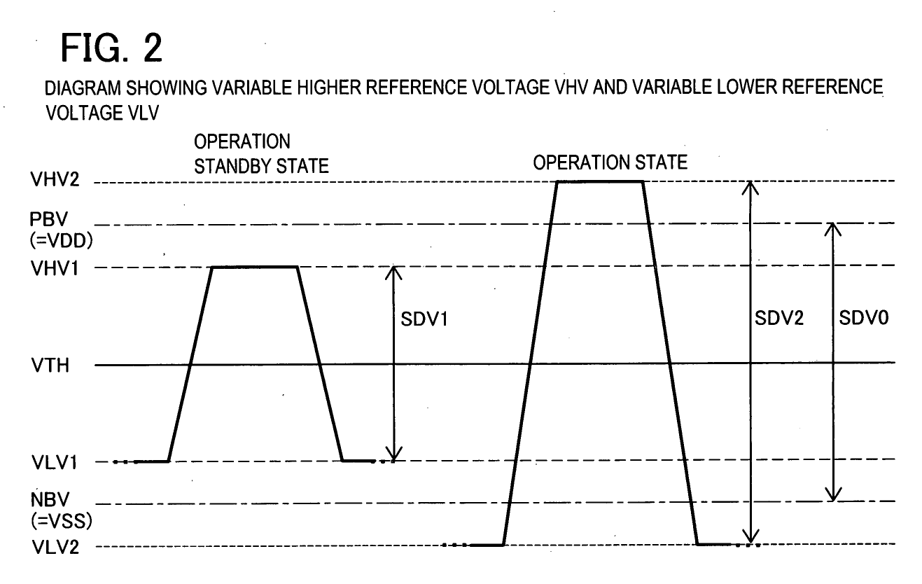

A first embodiment of the present invention will be described with reference to FIGS. 1 and 2. FIG. 1 shows a semiconductor integrated circuit 10 according to the present invention. The semiconductor integrated circuit 10 includes a voltage generator 11, an inverter circuit 12 as a representative circuit, a voltage control circuit 13, and a PLL circuit 14. A control signal CS is outputted from the voltage control circuit 13, and the control signal CS is inputted to the voltage generator 11 and the PLL circuit 14. Also, a clock signal CLK having a clock frequency corresponding to the control signal CS is outputted from the PLL circuit 14.

A variable higher reference voltage VHV and a variable lower reference voltage VLV are outputted from the voltage generator 11. The variable higher reference voltage VHV and the variable lower reference voltage VLV are variably controlled in the voltage level according to the control signal CS. The control of the voltage level is realized, for example, by selecting one of plural voltage generator circuits according to the control signal CS. The plural voltage generator circuits that step up and down the supply voltage VDD and the ground voltage VSS, and a select switch that selects any one of the voltage generator circuits are disposed in the voltage generator 11. Then, the voltage generator circuits that step up the supply voltage VDD and step down the ground voltage VSS is provided with a charge pump or the like. Also, the step down of the supply voltage VDD and the step up of the ground voltage VSS are conducted by using a resistive potential divider and a comparator.

The inverter circuit 12 is formed of a CMOS inverter including a PMOS transistor M10 and an NMOS transistor M11. The gates of the PMOS transistor M10 and the NMOS transistor M11 are commonly connected to an input terminal IN, and the drain terminal is commonly connected to an output terminal OUT. A back gate of the PMOS transistor M10 is connected to the supply voltage VDD that is a fixed voltage. Also, the back gate of the NMOS transistor M11 is connected to the ground voltage VSS that is a fixed voltage. A source terminal of the PMOS transistor M10 is connected to the voltage generator 11, and is applied with a variable higher reference voltage VHV. A source terminal of the NMOS transistor M11 is connected to the voltage generator 11 and applied with the variable lower reference voltage VLV.

The operation and effects of the semiconductor integrated circuit 10 will be described below. First, the operation at the time of the low power consumption (in the operation standby state) will be described. A CPU not shown informs the voltage control circuit 13 of the fact that the semiconductor integrated circuit 10 is made in a standby state. The control signal CS indicating that the variable higher reference voltage VHV is changed to a first level voltage value and the variable lower reference voltage VLV is changed to a third level voltage value are outputted from the voltage control circuit 13, and then inputted to the voltage generator 11. As shown in FIG. 2, a variable higher reference voltage VHV1 that is the first level voltage value which is equal to or lower than the back gate voltage value PBV (supply voltage VDD) of the PMOS transistor is outputted from the voltage generator 11 according to the control signal CS. Also, a variable lower reference voltage VLV1 that is the third level voltage value which is equal to or higher than the back gate voltage value NBV (ground voltage VSS) of the NMOS transistor is outputted from the voltage generator 11. Also, the control signal CS is also inputted to the PLL circuit 14. The frequency of the clock signal CLK that is outputted from the PLL circuit 14 is lowered according to the control signal CS.

In this case, because the threshold voltages of the PMOS transistor M10 and the NMOS transistor M11 become large due to the substrate bias effect, the leakage current between the source and the drain can be reduced. As a result, it is possible to reduce the power consumption of the inverter circuit 12 in the operation standby state, and it is also possible to reduce the power consumption of the semiconductor integrated circuit 10. Also, the power consumption of the semiconductor integrated circuit 10 is reduced by lowering the frequency of the clock signal CLK.

Subsequently, the operation of the semiconductor integrated circuit 10 at the time of (during) the high speed operation will be described. A CPU not shown informs the voltage control circuit 13 of the fact that the semiconductor integrated circuit 10 is made in the operation state. The control signal CS indicating that the variable higher reference voltage VHV is changed to the second level voltage value and the variable lower reference voltage VLV is changed to the fourth level voltage value are outputted from the voltage control circuit 13, and then inputted to the voltage generator 11. As shown in FIG. 2, a variable higher reference voltage VHV2 that is set to a second level voltage value which is higher than the back gate voltage value PBV (supply voltage VDD) of the PMOS transistor is outputted from the voltage generator 11 according to the control signal CS. Also, a variable lower reference voltage VLV2 that is set to a fourth level voltage value which is lower than the back gate voltage value NBV (ground voltage VSS) of the NMOS transistor is outputted from the voltage generator 11. Further, the control signal CS is also inputted to the PLL circuit 14. The frequency of the clock signal CLK that is outputted from the PLL circuit 14 increases according to the control signal CS.

In this case, it is possible to increase the operation speed of the transistor due to the above two effects. First, as a first effect, there can be obtained the effect that the high speed operation of the MOS transistor can be performed because the threshold voltage is reduced due to the substrate bias effect. Also, as a second effect, there can be obtained the effect that the high speed operation of the transistor can be performed because the voltage differences between the sources and the drains of the PMOS transistor M10 and the NMOS transistor M11 become large as compared with the voltage difference between the source and the drain in the case where the supply voltage VDD and the ground voltage VSS are employed as the source voltage. Then, the high speed operation of the transistor during the operation of the semiconductor integrated circuit 10 can be performed with higher efficiency. Then, the operation speed of the transistor is increased, and a gate delay time of a MOS logic gate provided in the semiconductor integrated circuit 10 is reduced, to thereby perform the high speed operation of the semiconductor integrated circuit 10. Also, even if the frequency of the clock signal CLK is made higher according to the control signal CS, the high speed operation of the semiconductor integrated circuit 10 is performed.

Then, it is possible to optimize the second and fourth level voltage values (variable higher reference voltage VHV2 and variable lower reference voltage VLV2) according to the required specification of the semiconductor integrated circuit. That is, the value of the voltage difference SDV2 may be set according to the required operation speed of the transistor. In this case, attention must be paid to the fact that the value of the voltage difference SDV2 should be set to fall within an allowable range of the withstand voltage between the sources and the drains of the PMOS transistor M10 and the NMOS transistor M11.

As described above in detail, according to the semiconductor integrated circuit of the present invention, the leakage current between the source and the drain in the PMOS transistor M10 and the NMOS transistor M11 can be reduced in the standby state because the threshold voltage becomes large due to the substrate bias effect, thereby making it possible to reduce the power consumption of the semiconductor integrated circuit 10. Also, in the operation state, as the first effect, it is possible to perform the high speed operation of the MOS transistor because the threshold voltage is made small due to the substrate bias effect. Also, as the second effect, it is possible to perform the high speed operation of the transistor because the voltage difference between the source and the drain of the PMOS transistor M10 and the NMOS transistor M11 becomes large. The synthetic effect of the above two effects makes it possible to more efficiently perform the high speed operation of the MOS transistor.

The method of the present invention enhances the efficiency of the high speed operation of the transistor more than that in the conventional method that adjusts the back gate voltage. Accordingly, in the case where the required operation speed specification according to the method of the present invention is equal to that in the conventional method, it is possible to suppress the variation width of voltage in the variation of the source voltage value according to the present invention more than that in the variation of the back gate voltage value. As a result, the power consumption at the time of changing the voltage can be reduced, and a period of time required for changing the voltage can be reduced.

Also, in the present invention, the back gate voltage value of the MOS transistor is fixed, and the source voltage value is variable. That is, in the case where the back gate voltage value is controlled, because a capacity of the back gate between the power supplies is very large, the power consumption is large, and a period of time required for changing the voltage is also large. However, in the present invention, because the source voltage value is controlled, a parasitic capacity is small. Therefore, the power consumption can be reduced at the time of changing the voltage, and a period of time required for changing the voltage can be also shortened. As a result, it is possible to suppress the power consumption at the time of transition between the standby state and the operation state. Also, since a period of time required for changing the voltage can be reduced, a period of time required for transition of from the standby mode (lower power consumption state) to the operation mode (high speed operation state) can be reduced, thereby making it possible to perform high speed start.

Also, in the present invention, the back bias value of the MOS transistor is fixed, and the source voltage value is variable. Accordingly, the voltage that is applied to the gate is kept constant, and there is no case in which a voltage that is applied to the gate becomes high as in the case where the back bias is varied so that a situation in which the gate leakage current increases can be prevented. Also, it is possible to prevent such problems that the transistor is deteriorated to shorten the lifetime of the LSI and that the reliability of the LSI is deteriorated, which result from applying a high voltage to the gate.

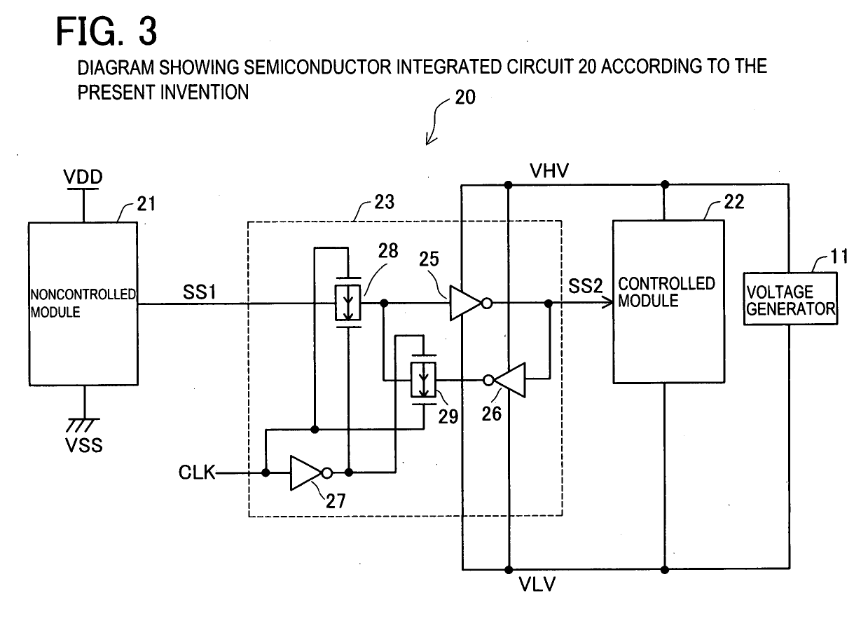

A second embodiment of the present invention will be described with reference to FIG. 3. In the second embodiment, the voltage amplitude of the output signal is adjusted at the time of inputting and outputting a signal between the modules to prevent the occurrence of a leakage current in the input side module. FIG. 3 shows a semiconductor integrated circuit 20 according to the present invention. The semiconductor integrated circuit 20 is a synchronous circuit that is synchronous with a clock signal CLK. The semiconductor integrated circuit 20 is equipped with a non controlled module 21 and a controlled module 22. The non controlled module 21 is a module in which a source power supply of a transistor is fixed, and the operation speed is not controlled. Then, a supply voltage VDD and a ground voltage VSS are supplied to the non controlled module 21 as an operation power supply. Also, the controlled module 22 is a module in which the source power supply of the transistor is variable, and the operation speed is controlled. Then, a variable higher reference voltage VHV and a variable lower reference voltage VLV are applied to the controlled module 22 from a voltage generator 11 as the operation power supply.

An output terminal of the non controlled module 21 and an input terminal of the controlled module 22 are connected to each other through a synchronous level converter portion 23. The synchronous level converter portion 23 is equipped with inverters 25 to 27 and transfer gates 28, 29. The inverters 25 and 26 constitute a latch circuit. Also, the transfer gate 28 is a switch circuit that shuts off a signal path between the non controlled module 21 and the controlled module 22. A signal SS1 that is outputted from the non controlled module 21 is inputted to a synchronous level converter portion 23. Also, a clock signal CLK is inputted to the synchronous level converter portion 23. The clock signal CLK is inputted to one gate of transfer gates 28 and 29, and also inputted to the other gate of the transfer gates 28 and 29 after being inverted by an signal inverter 27. A signal SS2 is outputted from the inverter 25 of the synchronous level converter portion 23, and then inputted to the controlled module 22.

The inverters 25 and 26 input the variable higher reference voltage VHV and the variable lower reference voltage VLV as the operation power supply. The voltage values of the variable higher reference voltage VHV and the variable lower reference voltage VLV are determined according to the operation speed and the power consumption of the semiconductor integrated circuit 20. Then, the amplitudes of the signals that are outputted from the non controlled module 21 and the controlled module 22 depend on the operation supply voltage while substantially centering a threshold voltage value VTH.

The operation of the semiconductor integrated circuit 20 will be described below. First, a description will be given of a case in which the voltage amplitude of a signal that is inputted to the controlled module 22 is smaller than the operation supply voltage difference of the controlled module 22. For example, a description will be given of a case in which the operation supply voltage of the controlled module 22 is set to second and fourth voltage values (variable higher reference voltage VHV2 and variable lower reference voltage VLV2 (FIG. 2)), and the operation supply voltage difference is set to a voltage difference SDV2. In this situation, the amplitude of the signal SS1 that is outputted from the non controlled module 21 is set to a voltage difference SDV0 (FIG. 2) between the supply voltage VDD and the ground voltage VSS, which is the operation supply voltage. Then, the voltage difference SDV0 does not make full amplitude from the viewpoint of the voltage difference SDV2 of the operation supply voltage of the controlled module 22. Accordingly, when the signal SS1 is directly inputted to the controlled module 22 while this state is maintained, a leakage current occurs in the interface circuit portion of the controlled module 22. As a result, there may occur an event that the power saving of the semiconductor integrated circuit 20 cannot be performed. Under the circumstances, it is important to input the signal through the synchronous level converter portion 23, thereby preventing the leakage current from occurring in the controlled module 22 and the current from being consumed between the modules.

The operation of the synchronous level converter portion 23 will be described below. In the synchronous level converter portion 23, when the clock signal CLK of a low level is inputted to the converter portion 23, the transfer gate 28 is rendered conductive and the transfer gate 29 is rendered nonconductive. As a result, the signal SS1 is received in the converter portion 23. In this situation, the signal SS1 is inputted to the inverter 25, however the signal SS1 does not make full amplitude from the viewpoint of the voltage difference SDV2 of the operation supply voltage of the controlled module 22. Therefore, the leakage current may flow in the inverter 25.

Then, in a succeeding cycle, when the clock signal CLK of a high level is inputted to the converter portion 23, the transfer gate 28 is rendered nonconductive and the transfer gate 29 is rendered conductive. As a result, the latched signal is outputted from the converter portion 23. Also, because the transfer gate 28 is rendered nonconductive, the signal path between the non controlled module 21 and the controlled module 22 is shut off. In this situation, because the output signal of the full amplitude from the inverter 26 is inputted to the inverter 25, no leakage current occurs in the inverter 25. Then, a signal SS2 having full amplitude at the time of a voltage difference SDV2 is outputted from the inverter 25. As a result, because the amplitude of the signal SS2 coincides with the operation supply voltage difference of the controlled module 22 at the time of the voltage difference SDV2, it is possible to prevent the leakage current from occurring in the interface circuit portion of the controlled module 22.

That is, the synchronous level converter portion 23 receives the signal SS1 and outputs the signal SS2 in synchronism with the clock signal CLK. With this operation, the synchronous level converter portion 23 receives a signal that is outputted from the non controlled module 21 while preventing an interference of the non controlled module 21 with the controlled module 22. Then, the synchronous level converter portion 23 converts the voltage level of the signal and transmits the signal to the controlled module 22. As a result, because the leakage current can be prevented from occurring in the controlled module 22, it is possible to reduce the power consumption in the semiconductor integrated circuit 20.

Subsequently, a description will be given of a case in which the voltage amplitude of the signal that is inputted to the controlled module 22 is larger than the operation supply voltage difference of the controlled module 22. For example, a description will be given of a case in which the operation supply voltage of the controlled module 22 is set to the first and third level voltage values (the variable higher reference voltage VHV1 and the variable lower reference voltage VLV1 (FIG. 2)), and the operation supply voltage difference is set to the voltage difference SDV1. In this situation, the amplitude of the signal SS1 that is outputted from the non controlled module 21 is set to the voltage difference SDV0 between the supply voltage VDD and the ground voltage VSS. As a result, the voltage difference SDV0 has full amplitude from the viewpoint of the voltage difference SDV1 in the operation supply voltage of the controlled module 22 and the synchronous level converter portion 23. Accordingly, no leakage current flows in the inverter 25 of the synchronous converter portion 23 regardless of the high or low level of the clock signal CLK. Then, because the amplitude (voltage difference SDV1) of the signal SS2 that is outputted from the inverter 25 coincides with the operation supply voltage difference of the controlled module 22, it is possible to prevent the leakage current from occurring in the interface circuit portion of the controlled module 22.

As described above in detail, according to the semiconductor integrated circuit of the second embodiment, since the synchronous level converter portion 23 having the switch circuit and the latch circuit is disposed in the signal path between the circuit blocks that are different in the operation supply voltage from each other, the leakage current is prevented from occurring in the circuit block at a side to which the signal is inputted, thereby making it possible to reduce the power consumption in the semiconductor integrated circuit 20.

The present invention is not limited to the above embodiment, and it is needless to say that various improvements or modifications are enabled within a scope that does not deviate from the sprit of the present invention. In the above embodiment, the control signal CS consists of a binary signal that informs the voltage control circuit of the standby state (lower consumption power state) and the operation state (high speed operation state). However, the present invention is not limited to this embodiment. The control signal CS may consist of a signal that informs the voltage control circuit of plural statuses. With this structure, for example, fine control can be performed such that the source voltage or the clock frequency can be switched to plural levels according to the required operation speed and power consumption even during the operation, thereby making it possible to further reduce the power consumption.

Also, in the first embodiment, the back gate voltage is fixed, and the source voltage is variably controlled. However, the present invention is not limited to this structure. The back gate voltage value may be controlled such that the difference voltage of the back gate voltage with respect to the source voltage is variable between the negative voltage and the positive voltage. Similarly, with this structure, the difference voltage can be variably controlled so that the threshold voltage becomes large in the case where power saving is going to be conducted, and the difference voltage can be variably controlled so that the threshold voltage becomes small in the case where the processing speed at the time of operation is required. As a result, it is possible to perform both of the power saving due to a reduction in the leakage current between the power supplies and the high speed operation of the MOS transistor at the time of operation.

Also, in the first embodiment, the voltage control circuit 13 outputs the control signal CS according to the information such as the standby or operation from a CPU not shown. However, the present invention is not limited to this structure. For example, it is possible that the voltage control circuit 13 is equipped with a sensor that detects a gate delay time of the MOS logic gate, and the control signal CS corresponding to the detected delay time is outputted from the voltage control circuit 13. As the sensor that detects the delay time, there is a generally used sensor due to delay. For example, the sensor is designed in such a manner that plural flip flops are connected in series, and outputs of the respective flip flops when a pulse signal is inputted to the flip flops are compared with each other to detect a delay time. With the above structure, the operation speed of the transistor can be increased by controlling the source voltage according to the delay time. As a result, there can be obtained not only the effect that the operation speed increases, but also the effect that an influence of a variation in the delay time which is attributable to the manufacture variation of the semiconductor integrated circuit 10 is canceled.

Also, it is possible that the operation frequency of the semiconductor integrated circuit 10 is variably controlled, and the values of the variable higher reference voltages VHV and the variable lower reference voltages VLV corresponding to the respective frequencies are set in advance and then held in the voltage control circuit 13. Then, it is possible that the source voltage value may be changed on the basis of the data held in the voltage control circuit 13 in response to a change in the operation frequency. Similarly, with this structure, fine control can be performed such that the source voltage is changed to plural levels according to the clock frequency, and the power consumption can be further reduced.

Further, in the first embodiment, the source voltage value is variably controlled in both of the PMOS transistor and the NMOS transistor. However, the present invention is not limited to this structure, and the source voltage value may be controlled in at least one transistor. In particular, the PMOS transistor is lower in the operation speed than the NMOS transistor. Therefore, the voltage control of the present invention is conducted on the source voltage value of the PMOS transistor, thereby making it possible to effectively increase the operation speed of the semiconductor integrated circuit while simplifying the circuit structure.

Further, in FIG. 2 of the first embodiment, the variable higher reference voltage VHV1 is lower than the back gate voltage value PBV, and the variable lower reference voltage VLV1 is higher than the back gate voltage value NBV. However, the present invention is not limited to this structure. It is possible that the variable higher reference voltage VHV1 is equal to the back gate voltage value PBV, and the variable lower reference voltage VLV1 is equal to the back gate voltage value NBV. As a result, the circuit structure of the voltage generator 11 can be simplified, and the operation speed of the transistor can be improved in the operation.

Further, in FIG. 2 of the first embodiment, a voltage that steps up from the supply voltage VDD is employed for the variable higher reference voltage VHV2, and a voltage that steps down from the ground voltage VSS is employed for the variable lower reference voltage VLV2. However, the present invention is not limited to this structure. For example, it is possible that the variable higher reference voltage VHV2 is set to the supply voltage VDD, and the variable lower reference voltage VLV2 is set to the ground voltage VSS. In this case, the back gate voltage values PBV, NBV, the variable higher reference voltage VHV1, and the variable lower reference voltage VLV1 are set to voltage values between the supply voltage VDD and the ground voltage VSS. As a result, because it is unnecessary to step up the supply voltage VDD or step down the ground voltage VSS, no charge pump that occupies a large circuit area is required, thereby making it possible to reduce the circuit in size. Also, the supply voltage VDD and the ground voltage VSS that are the operation power supply can be employed for the source voltage (variable higher reference voltage VHV2, variable lower reference voltage VLV2) during the operation. Accordingly, there is advantageous in that a fear that the malfunction occurs can be reduced because the source voltage can be readily stabilized.

Further, in the second embodiment (FIG. 3), the signal SS1 is received and outputted to a succeeding stage according to the clock signal CLK. However, the present invention is not limited to this structure. For example, it is possible that one shot pulse of the low level which has been generated by triggering the level transition of the inputted signal SS1 is inputted to the transfer gate 28, thereby rendering the transfer gate 28 conductive only when the signal SS1 transmits. With this structure, the leakage current in the inverter 25 can be reduced without receiving the signal SS1 every cycle of the clock signal CLK.

Further, in the second embodiment (FIG. 3), the connection between the non controlled module 21 and the controlled module 22 is described. However, it is needless to say that both of the connected modules are formed of controlled modules. In this event, in the case where the operation supply voltage difference of the controlled module at the signal output side is smaller than the operation supply voltage difference of the controlled module at the signal input side, the operation power supply of the controlled module at the signal input side may be supplied to the synchronous level converter portion 23. On the other hand, in the case where the operation supply voltage difference of the controlled module at the signal output side is larger than the operation supply voltage difference of the controlled module at the signal input side, the operation supply voltage of the controlled module at the signal output side may be supplied to the synchronous level converter portion 23. With this structure, the voltage level conversion is appropriately conducted in the synchronous level converter portion 23, and the leakage current is prevented from occurring in the controlled module at the signal input side, thereby making it possible to reduce the power consumption in the semiconductor integrated circuit 20.

Further, in the second embodiment (FIG. 3), the signal SS1 is inputted to the controlled module 22 after being subjected to level conversion through the synchronous level converter portion 23. However, the present invention is not limited to this embodiment. For example, it is possible that one path that is routed through the synchronous level converter portion 23 and another path that directly connects both of the non controlled module 21 and the controlled module 22 are provided in the path of from the non controlled module 21 to the controlled module 22, and a changeover switch that changes over between those paths is provided. In this event, in the case where the amplitude of the signal SS1 is smaller than the operation supply voltage difference of the controlled module 22, the path that is routed through the synchronous level converter portion 23 is selected. Also, in the case where the amplitude of the signal SS1 is larger than the operation supply voltage difference of the controlled module 22, the path that allows direct input is selected.

In the case where the circuit scale of the controlled module 22 is large, it is preferable from the viewpoint of design that plural voltage generators 11 are provided. As a result, because the source voltage can be stabilized, those voltage generators can contribute to the stable operation of the semiconductor integrated circuit 20.

The supply voltage VDD is an example of the higher reference voltage, and the ground voltage VSS is an example of the lower reference voltage.

According to the present invention, a difference voltage of the back gate terminal voltage with respect to the source terminal voltage of the MOS transistor is variably controlled between the negative voltage and the positive voltage. In the case where power saving is going to be conducted, the difference voltage is variably controlled so that the threshold voltage becomes large. In the case where the processing speed is required during the operation or the like, the difference voltage is variably controlled so that the threshold voltage becomes small. As a result, it is possible to perform both of the power saving due to a reduction in the leakage current between the supply voltages and the high speed operation of the MOS transistor during the operation.

What is claimed is:

1. A semiconductor integrated circuit, comprising:
a MOS transistor having a difference voltage of a back gate terminal voltage with respect to a source terminal voltage variously controlled among a negative voltage, a zero voltage and a positive voltage.

2. The semiconductor integrated circuit according to claim 1, wherein the source terminal voltage is variably controlled.

3. The semiconductor integrated circuit according to claim 1, wherein the difference voltage of a PMOS transistor is set to the positive voltage, and the difference voltage of an NMOS transistor is set to the negative voltage at the time of low power consumption, and
wherein the difference voltage of the PMOS transistor is set to the negative voltage, and the difference voltage of the NMOS transistor is set to the positive voltage at the time of high speed operation.

4. The semiconductor integrated circuit according to claim 3, wherein in the high speed operation, the source terminal voltage of the PMOS transistor is set to a supply voltage, and the source terminal voltage of the NMOS transistor is set to a ground voltage.

5. The semiconductor integrated circuit according to claim 1, further comprising a MOS logic gate.

6. The semiconductor integrated circuit according to claim 1, wherein a switch circuit and a latch circuit that inputs a signal through the switch circuit and is applied with the operation supply voltage of the circuit block to which the signal is outputted are disposed in a signal path between circuit blocks that are different in the operation supply voltage from each other.

7. The semiconductor integrated circuit according to claim 1, wherein a switch circuit and a latch circuit that inputs a signal through the switch circuit and is applied with the operation supply voltage of the second level voltage value or/and the fourth level voltage value are disposed in a signal path between circuit blocks that are different in the operation supply voltage from each other.

8. The semiconductor integrated circuit according to claim 6, wherein a clock signal is inputted to the switch circuit, and the signal is taken in the latch circuit according to the clock signal.

9. The semiconductor integrated circuit according to claim 7, wherein a clock signal is inputted to the switch circuit, and the signal is taken in the latch circuit according to the clock signal.

10. A method of controlling semiconductor integrated circuit, comprising the step of:
variably controlling a difference voltage of a back gate terminal voltage with respect to a source terminal voltage of a MOS transistor among a negative voltage, a zero voltage and a positive voltage.
